(19) United States
(12) Patent Application Publication
(10) Pub. No.: US 2007/0296423 A1
(43) Pub. Date: Dec. 27, 2007

(54) Double-sided wafer probe

(76) Inventors: Michael B. Whitener, Santa Rosa, CA (US); Allen L. Anderson, Santa Rosa, CA (US); John D. Larson III, Palo Alto, CA (US); Matt Condron, Santa Rosa, CA (US); Stephen R. Gilbert, San Francisco, CA (US); Jose Marroquin, Sebastopol, CA (US); Matthew R. Richter, Santa Rosa, CA (US); Ron Strehlow, Santa Rosa, CA (US); Hassan Tanbakuchi, Santa Rosa, CA (US); David V. Taylor, San Mateo, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/442,070

(22) Filed: May 25, 2006

(51) Int. Cl. G01R 31/02

(52) U.S. Cl. 324/754

(57) ABSTRACT

A wafer support assembly has a first wafer support plate having a first grid pattern allowing first probe access through the first grid pattern to a first side of a wafer in the wafer support assembly and a second wafer support plate having a second grid pattern allowing second probe access through the second grid pattern to a second side of the wafer in the wafer support assembly.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### BACKGROUND OF THE INVENTION

Integrated circuits (“ICs”) are often tested before they are separated from a wafer into individual chips. Such testing is commonly referred to as wafer-level test, and uses probes to contact probe sites on the wafer. Historically, semiconductor devices have been fabricated on a single side of a wafer, and probing solutions have been developed for single-sided probing. A variety of wafer probe stations are commercially available for single-sided wafer probing.

A vacuum chuck is often used to hold the wafer in place at a probe station, and probes are then aligned to the probe sites, often using a microscope for alignment. Sometimes individual probes are each aligned to corresponding probe sites, and other times a probe card, which as several probes fixed in an array around a central opening, is aligned to the corresponding probe sites, or the wafer is aligned to the probe card.

Recent developments in various areas of technology, such as emission spectroscopy, optical ICs, and micro-electro-mechanical systems (“MEMS”), have created a need to probe both sides of a wafer, and in particular instances, to probe both sides of a wafer simultaneously. Vacuum chucks used in conventional probe stations interfere with access to the “backside” of the wafer (i.e. the side of the wafer in contact with the vacuum chuck).

Backside and double-sided wafer probing stations, such as MP300™ and 8000 Series™, are available from THE MICROMANIPULATOR COMPANY of Carson City, Nev. This system is configured essentially the same as a single-sided wafer probing station that fixes the wafer horizontally. Alignment of the probes to contacts (probe sites) on the top of the wafer is achieved either with the aid of an optical microscope or camera mounted above the wafer. A camera mounted below the wafer aids the alignment of the probe to the bottom side (“backside”) of the wafer. Unfortunately, this system lacks the ability to easily probe pieces of broken wafers, which might contain several highly desirable ICs or be very important test wafers, and has limited accessibility to the surface of the wafer while they are mounted for testing.

A technique for simultaneously probing both sides of a wafer that overcomes the disadvantages of conventional probe stations is desirable.

### BRIEF SUMMARY OF THE INVENTION

A wafer support assembly has a first wafer support plate having a first grid pattern allowing first probe access through the first grid pattern to a first side of a wafer in the wafer support assembly and a second wafer support plate having a second grid pattern allowing second probe access through the second grid pattern to a second side of the wafer in the wafer support assembly.

### BRIEF DESCRIPTION OF THE DRAWINGS

FIG. 1A is an isometric view of a probe station according to an embodiment.

FIG. 1B is another isometric view of the probe station of FIG. 1A with the optical system swung out of the way for stage rotation.

FIG. 2 is a side view of a chassis assembly of a probe station according to an embodiment.

FIG. 3 is a perspective view of the rotating chassis assembly of FIG. 2.

FIG. 4 is a bottom view of a wafer support plate according to an embodiment.

FIG. 5 is an exploded isometric view of a wafer support assembly according to an embodiment.

FIGS. 6A-6D are plan views illustrating wafer placement using a series of shims.

FIG. 7 is a flow chart of a method of probing both sides of a wafer according to an embodiment.

### DETAILED DESCRIPTION OF THE EMBODIMENTS

Wafer probing stations according to embodiments of the invention easily accommodate a variety of wafer sizes and shapes. A rotating stage with a grid support allows simultaneous access to both sides of even irregularly shaped wafers. In some embodiments, a shim, which optionally includes a cut-out to accommodate a wafer or portion of a wafer, allows wafers of varying thickness to be probed, and can be used to position the wafer with respect to the support grid so that probe contact areas on the wafer are accessible by the probe.

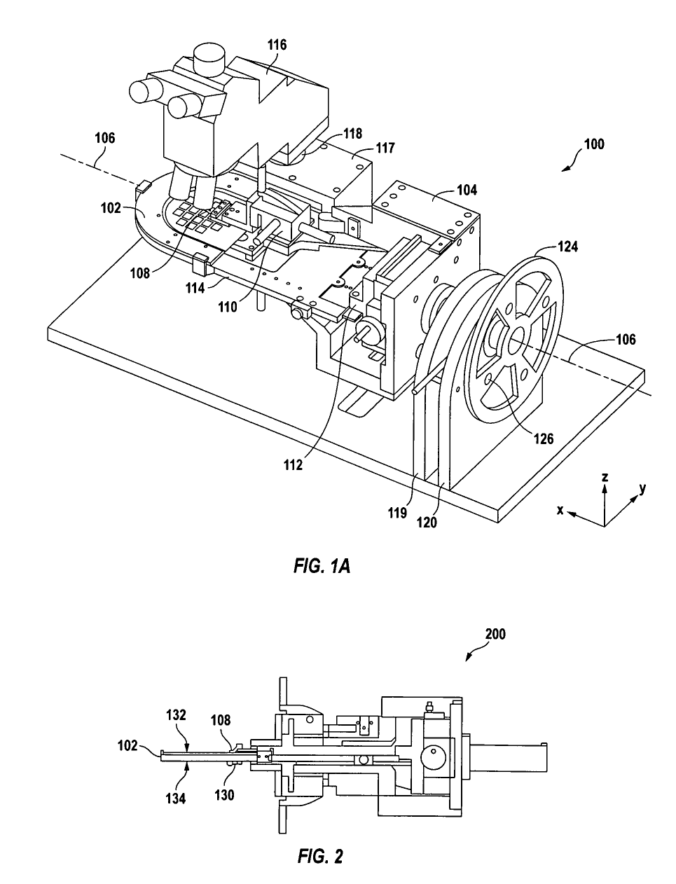

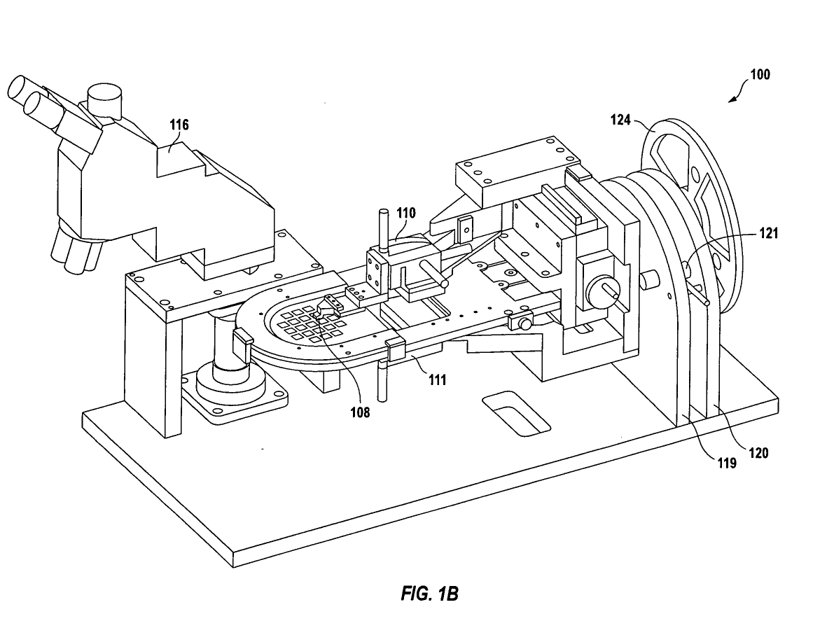

FIG. 1A is an isometric view of a probe station 100 according to an embodiment. A test wafer (not shown) is mounted in a wafer support assembly 102 mounted on a chassis 104. The chassis 104 is rotatable about an axis 106. A probe 108 mounted on a positioning stage 110 is adjustable in three axis (X, Y, and Z) to align the probe to a test site (contact) on the test wafer. A probe station optionally has additional probes and positioning stages (not shown) or one or more probe cards (not shown), as are well-known in the art of wafer probing.

The positioning stage 114 and probe 108 are mounted on a single-axis stage 112 that is adjustable in the Y direction for coarse adjustment of the wafer relative to the probe in one direction (e.g. the Z direction to raise and lower the probe and positioning stage) relative to the chassis 104. Similarly, the support structure 102 is mounted on a second single-axis stage 114 that is adjustable in one direction orthogonal to the axis of the other single-axis stage 112 (e.g. in the X direction, back and forth along the axis 106) relative to the chassis 104. The configuration of the two single-axis stages 112, 114 allows an operator to position the major plane (i.e. surface) of the test wafer with respect to the probe(s). In practice, the position of the test wafer is coarsely determined with the two single-axis stages 112, 114, and then the three-axis positioning stage 110 is used to accurately position the probe relative to a test pad on the wafer.

The entire chassis 104 supporting the test wafer, probe 108 (and backside probes), positioning stage 110, and wafer support structure 102 can be rotated about the axis 106, which provides several benefits. The rotation of the chassis 104 allows for the alignment of the probes to both sides of the wafer to be done with a single optical system (e.g. microscope or camera). This avoids having to provide a second optical system to align probes to the backside of the wafer.

A fixed reference can be obtained by alignment of the optical system to the axis of rotation of the chassis, which facilitates the relative position of the probes on the test wafer. In other words, the rotatable chassis allows a user to verify that proper probe contact is being made to both sides of the wafer) using a single optical system. Additionally, in cases where it may be desirable to fix the orientation of the wafer vertically, rotation of the chassis allows the wafer to be loaded in a convenient horizontal configuration, and then rotated to the desired vertical position for testing. The optical system 116 is supported by a pivot 118 that is independent of the chassis 104 and is connected to an optical chassis 117. The pivot 118 allows the optical system to swing out of the way around the Z axis so that it does not interfere with rotating the chassis.

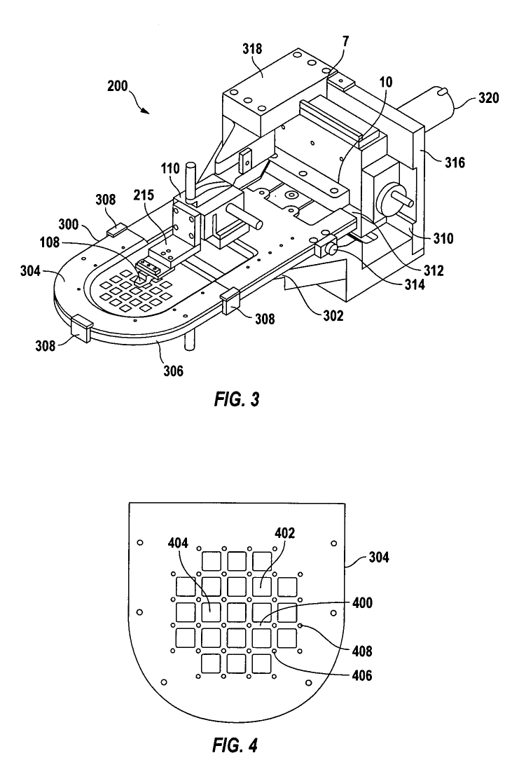

Brackets 119, 120, support the chassis assembly (see FIGS. 2, 3, ref. num. 200). A wheel 124 is used to turn the chassis assembly. When a predetermined rotation is obtained, the wheel 124 and chassis assembly are locked in place relative to the bracket 120 by inserting a pin (see FIG. 1B, ref. num. 121) through a hole (e.g. hole 126) held in a corresponding hole (not visible in this view) in the bracket 120, or by other locking mechanism. The rotational mechanism is merely exemplary, and other techniques, including automated or semi-automated techniques, are alternatively used for rotating the chassis assembly.

FIG. 1B is another isometric view of the probe station 100 of FIG. 1A with the optical system 116 swung out of the way for stage rotation. A second positioning stage 111 is visible on the chassis assembly on the wafer side opposite from the first positioning stage 110. The second positioning stage 111 has a probe (see FIG. 2, ref. num. 130) similar to the probe 108 attached to the first positioning stage 110. The pin 121 used to lock the wheel 124 relative to the brackets 119, 120.

FIG. 2 is a side view of a chassis assembly 200 of a probe station according to an embodiment. Probes 108, 130 mounted on the chassis assembly 200 contact a first side 132 and a second side 134 of a test wafer (not visible in this view) held in the wafer support assembly 102. In other words, probes are mounted on both sides of the test wafer. Alternative embodiments include additional probes on one or both sides of the test wafer. Similarly, in some embodiments, the wafer support structure 102 provides an electrical contact, such as a ground contact, to the test wafer through the chassis assembly 200.

FIG. 3 is a perspective view of the rotating chassis assembly 200 of FIG. 2. A wafer support assembly 300 is attached to a first single-axis stage 302. The wafer support assembly 300 may be separated from the chassis assembly to facilitate loading and unloading of the test wafer. The wafer support assembly includes a first wafer support plate 304 connected to a second wafer support plate (“stage”) 306 by clips 308 or other means. The second wafer support plate 306 is affixed a second single-axis stage 310 such that the motion of the first single-axis stage is orthogonal to the motion of the second single-axis stage. In a particular embodiment, the first single-axis stage has a dovetail 312 that is mounted to a ball screw-driven mechanism 314 to provide a sliding wafer stage. Locks on the drive mechanism 314 prevent movement after positioning. A variety of stage options are available beyond the dovetail and ball screw combination of this embodiment.

The probe is mounted to a three-axis stage 110 via a probe arm 215, and the three-axis stage 110 is mounted to the main chassis mount plate 316 via a support structure 318. The main chassis mount plate 316 mates with a shaft 320 that provides the axis of rotation (see FIG. 1A, ref. num. 106) for the chassis assembly 200. Probes (e.g. probe 108) are mounted on both the top and bottom of the chassis in the manner described.

The stability and positioning of the probes is important because movement of the probes will affect the test results and the probes are precisely aligned with the test sites (contacts) on the wafer. Stability of the probes is determined by the rigidity of the structure supporting them. The three-axis stages 110 typically have some play in them and it is advantageous to place these as close as possible to the probe to minimize the effect of such play. Positioning of the probes relative to the test sites on the wafer can be enhanced by building adjustability into the probe arm 215, specifically with respect to angular and yaw adjustment.

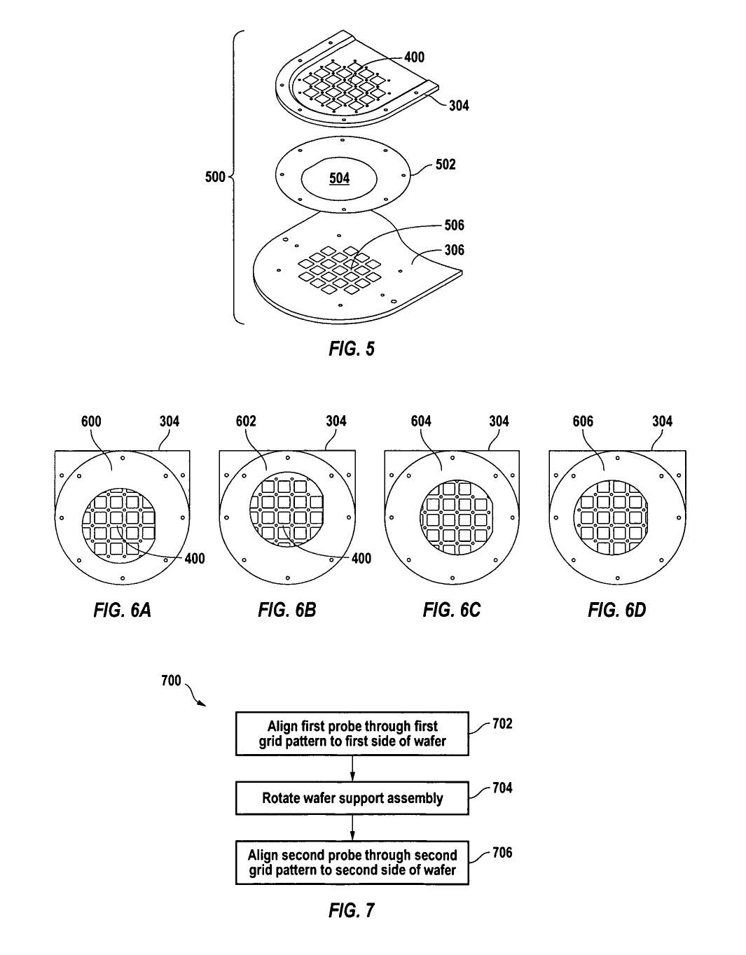

FIG. 4 is a bottom view of a wafer support plate 304 according to an embodiment. The wafer support plate 304 is part of the wafer support assembly (see FIG. 3, ref. num. 300). In a particular embodiment, a similar second wafer support plate is used in a wafer support assembly on the other side of the test wafer (see FIGS. 3, 5, ref. num. 306). Alternatively, the wafer support assembly uses different support plates on each side of the test wafer. The wafer support plate 304 has a grid pattern 400 with openings 402, 404 that allow access to probe sites (contacts) on the test wafer (not shown) while supporting the test wafer during probing. It is important that contacting the wafer with a probe does not damage the wafer, such as by cracking, and it is also important to support the wafer so that an adequate probing force can be obtained. Without sufficient support, probing force might crack a wafer or damage a feature of an IC, such as cracking a thin-film metal trace, or deflection of the wafer might alter electrical test results. Similarly, deflection of an inadequately supported wafer might prevent developing the desired amount of probing force.

Conventional probe stations typically support essentially the entire backside of a test wafer. Some probe stations include a small “window” in the backside support to allow backside probing access, but this limits the area available for probing to the relatively small window. The test wafer area covered by the grid pattern 400 of the wafer support plate 304 is relatively small compared to a conventional backside wafer support. Similarly, the grid pattern 400 allows probe access across the test wafer (other than the relatively small area covered by the grid). The size of the grid and openings can be varied as desired for use in particular applications, such as by matching the grid pattern to separation channels between ICs on a wafer. In a particular embodiment, the wafer support plate 304 is a separate piece that mounts to the chassis, which aids in loading and unloading of the wafer.

Compliant material 406, 408 is optionally included to account for slight differences in thickness between the test wafer and the shim (see FIG. 5, ref. num. 502). In a particular embodiment, compliant material, such as room-temperature vulcanizing silicone rubber (“RTV”) material, is provided on the bottom of the wafer support plate 304.

FIG. 5 is an exploded isometric view of a wafer support assembly 500 according to an embodiment. The wafer support assembly 500 includes a first wafer support plate 304, a shim 502, and a second wafer support plate 306, which in this view is a portion of the wafer support plate 306 of FIG. 4. The shim has a wafer pocket 504 that positions the test wafer with respect the grid patterns 400, 506 when the wafer support assembly is assembled. The thickness of the shim is chosen according to the thickness of the intended test wafer, which allows a single probe station to accommodate several different types of wafers by using corresponding shims of different thicknesses. This feature is particularly desirable in research environments where several different types of wafer sizes and materials are used.

Alignment pins are used to position the shim properly on the wafer support. The wafer support assembly 500 can also be used to test portions of a wafer, such as a piece of a broken wafer, particularly if compliant material (see, e.g., FIG. 4, ref. nums. 406, 408) on one or both of the wafer support plates or elsewhere in the wafer support assembly. Vacuum chucks often rely on a complete or nearly complete wafer in order to properly function. The first and second wafer support plates securely support even small, irregularly shaped pieces of wafers for simultaneous testing of both sides of the wafer piece.

The first wafer support plate 304 has a first grid pattern 400 allowing probe access to a first side of a wafer (see FIG. 2, ref. num. 132) when the wafer is mounted in the wafer support assembly, and the second wafer support plate 306 has a second grid pattern 506 allowing probe access to a second side of the wafer (see FIG. 2, ref. num. 134). The first and second grid patterns are the same in some embodiments, and are different in alternative embodiments.

FIGS. 6A-6D are plan views illustrating wafer placement using a series of shims 600, 602, 604, 606. The shims provide a simple, easy way of accommodating a variety of wafer thicknesses and configurations. Essentially any wafer that fits on the wafer support can be tested using an appropriate shim. A shim can also be used to position a test wafer on a support plate relative to the grid. This avoids the problem of the grid covering a desired test site on the wafer. A series of properly designed shims allows a wafer to be repositioned such that any site on the wafer can be probed. In addition as noted previously a shim having the appropriate thickness (typically the same as the wafer being tested) avoids crushing or cracking a wafer when it is secured in the wafer support assembly.

FIG. 6A shows a first shim 600 superimposed on the wafer support plate 304. During testing, a wafer is placed in the wafer pocket (see FIG. 5, ref. num. 504), which locates the test wafer over a first portion of the grid pattern 400. FIG. 6B shows a second shim 602 superimposed on the wafer support plate 304. Comparing FIG. 6B to FIG. 6A, it is seen that different portions of the test wafer will be exposed through the grid pattern 400. FIG. 6C shows a third shim 604 superimposed on the wafer support plate 304, and FIG. 6D shows a fourth shim 606 superimposed on the wafer support plate 304. All areas on a test wafer are accessible by properly selecting the grid spacing and shims/wafer pockets.

FIG. 7 is a flow chart of a method 700 of probing both sides of a wafer according to an embodiment. A first probe is aligned to a first test site on a first side of a wafer in a rotatable wafer support assembly through a first opening in a first grid pattern so as to contact the first test site (step 702). The wafer support assembly is rotated (step 704), and a second probe is aligned to a second test site on a second side of the wafer through a second opening in a second grid pattern so as to contact the second test site (step 706). In a particular embodiment, an optical system is used to align the first probe to the first test site, and the optical system is used to align the second probe to the second test site. In a further embodiment, the optical system is swung out of the way between steps 702 and 704, and swung back into position between steps 704 and 706. In a particular embodiment, the wafer support assembly is rotated about 180 degrees in step 704. In a particular embodiment, the wafer support assembly has a first grid pattern on a first side, and a second grid pattern on a second side, the first grid pattern being different from the second grid pattern. Alternatively, the grid patterns are essentially the same on the first and second sides of the wafer support assembly.

In a further embodiment, after step 706, the wafer is tested by simultaneously probing the first and second test sites. Then, a shim aligning the wafer to the first and second grids is removed from the wafer support assembly and replaced with a second shim to re-align the wafer to different portions of the first and second grids so as to expose one or more test sites that were previously covered.

While the preferred embodiments of the present invention have been illustrated in detail, it should be apparent that modifications and adaptations to these embodiments might occur to one skilled in the art without departing from the scope of the present invention as set forth in the following claims.

1. A wafer support assembly comprising:
a first wafer support plate having a first grid pattern allowing first probe access through the first grid pattern to a first side of a wafer in the wafer support assembly; and
a second wafer support plate having a second grid pattern allowing second probe access through the second grid pattern to a second side of the wafer in the wafer support assembly.

2. The wafer support assembly of claim 1 wherein the first grid pattern is essentially the same as the second grid pattern.

3. The wafer support assembly of claim 1 further comprising a first shim disposed between the first wafer support plate and the second wafer support plate.

4. The wafer support assembly of claim 3 wherein the shim has a wafer pocket overlying a first portion of the first grid pattern.

5. The wafer support assembly of claim 4 further comprising a second shim having a second wafer pocket overlying a second portion of the first grid pattern when the shim is replaced by the second shim in the wafer support assembly.

6. The wafer support assembly of claim 1 further comprising compliant material disposed between the wafer and at least one of the first wafer support plate and the second wafer support plate.

7. The wafer support assembly of claim 1 wherein at least one of the first wafer support plate and the second wafer support plate includes compliant material contacting the wafer.

8. The wafer support assembly of claim 1 further comprising a shaft allowing rotation of the wafer support assembly in a probe station.

9. The wafer support assembly of claim 8 further comprising an optical system of the probe station configured to view the first side of the wafer when the wafer support assembly is rotated to a first position and to view the second side of the wafer when the wafer support assembly is rotated to a second position.

10. The wafer support assembly of claim 1 wherein the first probe and the second probe concurrently contact the wafer to provide double-sided wafer probing.

11. The wafer support assembly of claim 1 wherein said first and second grid patterns comprise openings, wherein ones of said openings allow access to a plurality of probe sites of the wafer.

12. The wafer support assembly of claim 1 wherein the first and second grid patterns cover a small area of the wafer allowing access across the wafer.

13. The wafer support assembly of claim 1 wherein at least one of the first and second grid patterns matches separation channels between integrated circuits on the wafer.

14. The wafer support assembly of claim 3 wherein the first shim positions the wafer relative to at least one of the first and second grid patterns.

15. The wafer support assembly of claim 1 wherein the wafer is a piece of a broken wafer.

16. A method for probing a wafer, or a piece broken therefrom, comprising the steps of:
aligning a first probe to a first side of the wafer,
rotating a chassis to which are coupled the wafer and the first probe; and
aligning a second probe to a second side of the wafer.

17. The method of claim 16 wherein the first probe contacts a first test site of the wafer through an opening of a first grid pattern.

18. The method of claim 17 wherein the second probe contacts a second test site of the wafer through an opening of a second grid pattern.

19. The method of claim 16 further comprising the step of:
rotating an optical system to facilitate the rotating of the chassis.

20. The method of claim 16 further comprising the steps of:
rotating the chassis to a convenient position for loading the wafer; and
rotating the chassis to a desired position for testing the wafer.
